(19) United States
(12) Patent Application Publication
(10) Pub. No.: US 2024/0038922 A1
(43) Pub. Date: Feb. 1, 2024

(54) OPTICAL MODULE

(71) Applicant: Mitsubishi Electric Corporation, Tokyo (JP)

(72) Inventor: Junichi SUZUKI, Tokyo (JP)

(73) Assignee: Mitsubishi Electric Corporation, Tokyo (JP)

(21) Appl. No.: 18/379,996

(22) Filed: Oct. 13, 2023

Related U.S. Application Data
(63) Continuation of application No. PCT/JP2021/019345, filed on May 21, 2021.

(51) Int. Cl. H01L 31/173; H01L 31/0232

(52) U.S. Cl. CPC H01L 31/173; H01L 31/02325

(57) ABSTRACT

A lens array includes, on a surface which belongs to the lens array and which faces a flat surface of a base, a plurality of adhesive surfaces located side by side in a direction in which a plurality of lens elements is arranged in parallel, and includes an interference suppression portion for an adhesive between adjacent adhesive surfaces among the plurality of adhesive surfaces, and a plurality of adhesive layers is provided which glues the plurality of adhesive surfaces of the lens array to the flat surface of the base and thereby fixes the lens array to the flat surface of the base.

### CROSS REFERENCE TO RELATED APPLICATION

This application is a Continuation of PCT International Application No. PCT/JP2021/019345, filed on May 21, 2021, which is hereby expressly incorporated by reference into the present application.

### TECHNICAL FIELD

The present disclosure relates to an optical module provided with a lens array including a plurality of lens elements arranged in parallel.

### BACKGROUND ART

Patent Literature 1 discloses an optical device that condenses light output from a light source such as a laser diode with a lens and causes the light to be incident on an optical waveguide formed in an optical waveguide element.

The lens is an optical component integrated with an optical element holder. The optical component is interposed between two opposing pedestals and fixed onto the two pedestals with an adhesive. The two pedestals are fixed to a fixed base with an adhesive.

### CITATION LIST

### Patent Literature

Patent Literature 1: JP 2008-250002 A

### SUMMARY OF INVENTION

### Technical Problem

Recently, in the field of optical communication devices, a compact size, low power consumption, and cost reduction are required, and thus a technology of integrating a plurality of functions in one optical module attracts attention. In order to improve an integration degree, it is conceivable to make the optical module compact by disposing, between optical elements facing each other, a lens array including a plurality of lens elements arranged in parallel.

In a case where the lens array is fixed to a base, if the lens array is simply fixed to the two pedestals, between which the lens array is interposed, with the adhesive and then the two pedestals are fixed to the fixed base as disclosed in Patent Literature 1, the two pedestals are used, so that the number of components increases. Moreover, since a plurality of lens elements is arranged in parallel in the lens array, a length of the lens array in a horizontal direction in which the lens elements are arranged in parallel on the base is longer than a height of the lens array in a height direction, and the lens array itself is also made compact, so that the lens array disadvantageously inclines with respect to the horizontal direction.

That is, when the lens array is inclined with respect to the horizontal direction, there is a lens element whose core (center) is shifted in the height direction with respect to the optical axis of the optical elements facing each other, among the plurality of precisely aligned lens elements in the lens array.

As a result, a coupling efficiency difference might occur between the optical elements coupled via the lens elements.

The present disclosure has been made in view of the above points, and an object thereof is to obtain an optical module in which inclination of a lens array with respect to a flat surface of a base is suppressed.

### Solution to Problem

An optical module according to the present disclosure includes: a base including a flat surface; a semiconductor light emitter and a semiconductor light receiver arranged in such a manner as to face each other on the flat surface of the base, the semiconductor light emitter and the semiconductor light receiver each including a plurality of parallel optical axes, the semiconductor light emitter being to emit light to the plurality of optical axes, the semiconductor light receiver being to receive the light emitted from the semiconductor light emitter to the plurality of optical axes; and a lens array disposed on the flat surface of the base between the semiconductor light emitter and the semiconductor light receiver, the lens array including a plurality of lens elements arranged in parallel, the plurality of lens elements corresponding to the respective plurality of optical axes of each of the semiconductor light emitter and the semiconductor light receiver, the plurality of lens elements optically coupling the semiconductor light emitter to the semiconductor light receiver, in which the lens array includes, on a surface which belongs to the lens array and which faces the flat surface of the base, a plurality of adhesive surfaces located side by side in a direction in which the plurality of lens elements is arranged in parallel, and includes an interference suppression portion for an adhesive between adjacent adhesive surfaces among the plurality of adhesive surfaces, and a plurality of adhesive layers is provided which glues the respective plurality of adhesive surfaces of the lens array to the flat surface of the base and thereby fixes the lens array to the flat surface of the base.

### Advantageous Effects of Invention

According to the present disclosure, the lens array includes the plurality of adhesive surfaces and the interference suppression portion for the adhesive between the adjacent adhesive surfaces, and the plurality of adhesive layers fixed to the flat surface of the base is provided between the plurality of adhesive surfaces and the flat surface of the base. Thus, inclination of the lens array with respect to the flat surface of the base is suppressed.

### BRIEF DESCRIPTION OF DRAWINGS

FIG. 1 is a perspective view illustrating an optical module according to a first embodiment.

FIG. 2 is a front view illustrating a state in which first adhesive resin is applied to a lens array in the optical module according to the first embodiment.

FIG. 3 is a front view illustrating a state in which second adhesive resin is applied to the lens array in the optical module according to the first embodiment.

FIG. 4 is a front view illustrating a state in which the first adhesive resin and the second adhesive resin are applied to the lens array in the optical module according to the first embodiment to be cured, and thereby the lens array is fixed to a base.

FIG. 5 is a front view of a comparative example illustrating a state in which first adhesive resin is applied to a lens array.

FIG. 6 is a front view of the comparative example illustrating a state in which second adhesive resin is applied to the lens array.

FIG. 7 is a front view of the comparative example illustrating a state in which the first adhesive resin and the second adhesive resin are applied to the lens array to be cured, and thereby the lens array is fixed to the base.

FIG. 8 is a front view illustrating a state in which first adhesive resin and second adhesive resin are applied to a lens array in an optical module according to a second embodiment to be cured, and thereby the lens array is fixed to a base.

FIG. 9 is a perspective view illustrating an optical module according to a third embodiment.

FIG. 10 is a front view illustrating a state in which first adhesive resin and second adhesive resin are applied to a lens array in the optical module according to the third embodiment.

FIG. 11 is a front view illustrating a state in which the first adhesive resin and the second adhesive resin are applied to the lens array in the optical module according to the third embodiment to be cured, and thereby this is fixed to a base.

FIG. 12 is a front view illustrating a state in which first adhesive resin and second adhesive resin are applied to a lens array in an optical module according to a fourth embodiment.

FIG. 13 is a front view illustrating a state in which the first adhesive resin and the second adhesive resin are applied to the lens array in the optical module according to the fourth embodiment to be cured, and thereby this is fixed to a base.

### DESCRIPTION OF EMBODIMENTS

### First Embodiment

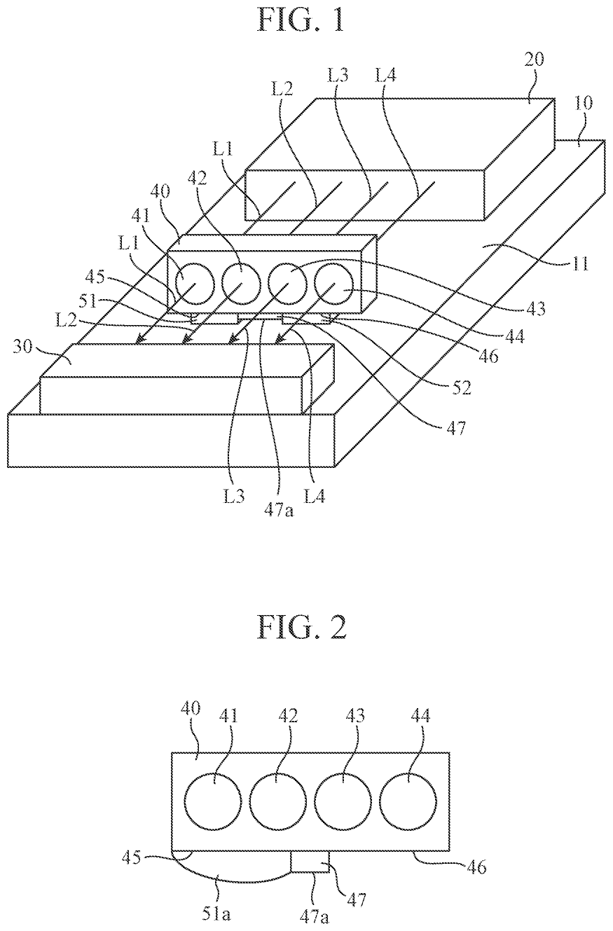

An optical module according to a first embodiment is described with reference to FIGS. 1 to 4.

The optical module according to the first embodiment is used for connecting optical fibers in the field of optical communication devices.

As illustrated in FIG. 1, the optical module according to the first embodiment is provided with a base 10, a first optical element 20, a second optical element 30, a lens array 40, a first adhesive layer 51, and a second adhesive layer 52.

In the optical module according to the first embodiment, a plurality of light beams emitted from the first optical element 20 is condensed by a plurality of lens elements 41 to 44 of the lens array 40 and optically coupled to the second optical element 30.

The base 10 is plate-shaped metal including a horizontal surface 11, which is a flat surface, and is fixed to a housing, a wall or the like.

In the base 10, the flat surface, which is the horizontal surface 11, is only required to be a flat surface on which the first optical element 20, the second optical element 30, and the lens array 40 may be fixed even if there are some steps or unevenness.

The first optical element 20 and the second optical element 30 are arranged in such a manner as to face each other on the horizontal surface 11 of the base 10. The first optical element 20 and the second optical element 30 each include a plurality of parallel optical axes L1 to L4.

In this example, four optical axes L1 to L4 are illustrated, and an optical path through which light emitted from the first optical element 20 is propagated to the second optical element 30 is formed along the optical axis.

The first optical element 20 is fixed on one end side of the horizontal surface 11 of the base 10 in such a manner that its position does not move with respect to the base 10.

The first optical element 20 is directly fixed to the horizontal surface 11 of the base 10, or directly fixed to the horizontal surface 11 of the base 10 in a state of being mounted on a submount such as a ceramic substrate.

The first optical element 20 is, for example, a surface light emitting type semiconductor laser. The first optical element 20 includes a plurality of optical axes L1 to L4 that emits light in an array to the other end side of the horizontal surface 11 of the base 10.

The first optical element 20 may be an optical element in which four semiconductor light emitting elements such as semiconductor lasers or light emitting diodes are incorporated as one module, or an optical element in which a demultiplexing path or a demultiplexer that demultiplexes light from one semiconductor light emitting element into four light beams is incorporated in the semiconductor light emitting element, instead of the surface light emitting type semiconductor laser.

The second optical element 30 is fixed on the other end side of the horizontal surface 11 of the base 10 in such a manner that its position does not move with respect to the base 10.

The second optical element 30 is, for example, a surface light receiving type photodiode. The second optical element 30 receives, in an array, light emitted from the first optical element 20 in an array.

The second optical element 30 may be an optical element in which four semiconductor light receiving elements such as photodiodes are incorporated as one module, or an optical element including four waveguides that performs optical processing such as modulation and amplification in each of the four waveguides, instead of the surface light receiving type photodiode.

In the first embodiment, it is described supposing that a direction connecting one end to the other end of the horizontal surface 11 of the base 10 is a longitudinal direction, a direction connecting one side to the other side of the horizontal surface 11 is a lateral direction, and a direction perpendicular to the horizontal surface is a vertical direction.

The optical axes L1 to L4 are axes in the longitudinal direction, and the plurality of optical axes L1 to L4 is arranged in parallel in the lateral direction.

The lens array 40 is disposed on the horizontal surface 11 of the base 10 between the first optical element 20 and the second optical element 30.

The lens array 40 includes the plurality of lens elements 41 to 44 which is arranged in parallel in the lateral direction and corresponding to the plurality of optical axes L1 to L4 of the first optical element 20 and the second optical element 30. The lens array 40 has a rectangular parallelepiped shape as a whole.

Each of the plurality of lens elements 41 to 44 is arrayed in a precisely aligned manner.

Cores (centers) of the plurality of lens elements 41 to 44 are on the corresponding optical axes L1 to L4 of the first optical element 20 and second optical element 30, respectively.

Each of the plurality of lens elements 41 to 44 is a convex lens that condenses light emitted from the first optical element 20 and guides the light to the second optical element 30. Each of the plurality of lens elements 41 to 44 optically couples the first optical element 20 to the second optical element 30.

The lens array 40 includes, on its surface facing the horizontal surface 11 of the base 10, that is, its bottom surface, a plurality of adhesive surfaces 45 and 46 located in a direction in which the plurality of lens elements is arranged in parallel, that is, in the lateral direction, and an interference suppression portion 47 for an adhesive between adjacent adhesive surfaces 45 and 46 out of the plurality of adhesive surfaces 45 and 46.

In this example, there are two adhesive surfaces 45 and 46. The first adhesive surface 45, which is one of the two, is the bottom surface located on one side in the lateral direction, and the second adhesive surface 46, which is the other one of the two, is the bottom surface located on the other side in the lateral direction. The adhesive surfaces 45 and 46 have the same area.

The interference suppression portion 47 is a protrusion provided at the center in the lateral direction on the bottom surface of the lens array 40, protruding toward the horizontal surface 11 of the base 10 with respect to the first adhesive surface 45 and the second adhesive surface 46, and having the same width as the width (in the longitudinal direction) of the bottom surface.

The interference suppression portion 47 including the protrusion is a metal body of a hexahedron, with an upper surface fixed to the bottom surface of the lens array 40, and a lower surface being a joining horizontal surface (joining flat surface) 47a in close contact with the horizontal surface 11 of the base 10.

Although the interference suppression portion 47 formed as a separate body on the bottom surface of the lens array 40 is illustrated, this may be formed integrally with the bottom surface of the lens array 40. In a case where this is integrally formed, this is simultaneously formed when the lens array 40 is formed.

Although there are two adhesive surfaces 45 and 46 in this example, a plurality of adhesive surfaces may be arranged at regular intervals. In a case of three or more adhesive surfaces, the areas of the respective adhesive surfaces are the same.

In a case where three or more adhesive surfaces are arranged, the interference suppression portion 47 is each protrusion provided between adjacent adhesive surfaces.

The adhesive layers 51 and 52 are adhesive layers that glue the plurality of adhesive surfaces 45 and 46 of the lens array to the horizontal surface 11 of the base 10 to fix the lens array 40 to the horizontal surface 11 of the base 10.

The adhesive layers 51 and 52 are formed of adhesive resin that has viscosity and glues the adhesive surfaces 45 and 46 of the lens array 40 to the horizontal surface 11 of the base 10 by being cured.

The number of adhesive layers 51 and 52 is the same as the number of adhesive surfaces 45 and 46.

Next, a method of mounting the lens array 40 on the horizontal surface 11 of the base 10 is described with reference to FIGS. 2 to 4.

First, as illustrated in FIG. 2, adhesive resin 51a is applied to the first adhesive surface 45 out of the plurality of adhesive surfaces 45 and 46 of the lens array 40.

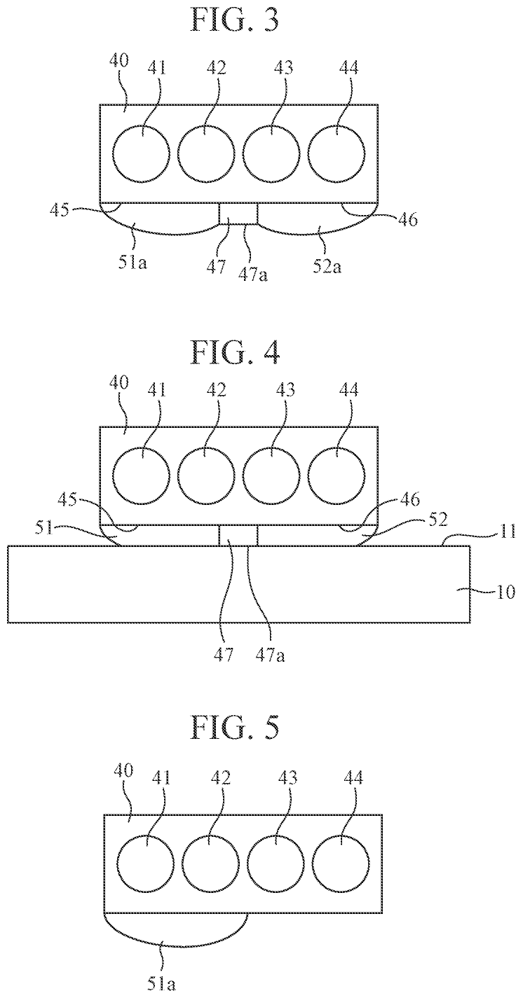

Subsequently, as illustrated in FIG. 3, adhesive resin 52a of the same application amount as that of the adhesive resin 51a is applied to the second adhesive surface 46 out of the plurality of adhesive surfaces 45 and 46 of the lens array 40.

Although the adhesive resin 51a and 52a has viscosity, the interference suppression portion 47 prevents the adhesive resin 52a applied later from flowing to the adhesive resin 51a. Thus, no interference occurs between the adhesive resin 51a and the adhesive resin 52a, and there is no difference in thickness of the application film between the adhesive resin 51a and the adhesive resin 52a. Thus, the application films of the adhesive resin 51a and the adhesive resin 52a have the same thickness.

In this state, the adhesive resin 51a and the adhesive resin 52a are cured with the joining horizontal surface 47a of the interference suppression portion 47 in the lens array 40 brought into close contact with the horizontal surface 11 of the base 10, as illustrated in FIG. 4. Thereby, the adhesive layers 51 and 52 glue the adhesive surfaces 45 and 46 of the lens array 40 to the horizontal surface 11 of the base 10, respectively, to firmly fix the lens array 40 to the horizontal surface 11 of the base 10 at two points in the lateral direction.

When the adhesive resin 51a and 52a is cured, shrinkage depending on the application thickness occurs in each of the adhesive resin 51a and the adhesive resin 52a. However, since the thickness of the application film of the adhesive resin 51a is the same as that of the adhesive resin 52a, the thicknesses of the adhesive layer 51 and the adhesive layer 52 are also the same.

As a result, the lens array 40 is not inclined in the lateral direction with respect to the horizontal surface 11 of the base 10 even though the lens array 40 is long in the lateral direction. That is, each of the cores (centers) of the plurality of lens elements 41 to 44 of the lens array 40 is located on a plane parallel to the horizontal surface 11 of the base 10, and is located on the corresponding one of the optical axes L1 to L4 of the first optical element 20 and the second optical element 30.

Since each of the cores (centers) of the plurality of lens elements 41 to 44 of the lens array 40 is located on the corresponding one of the optical axes L1 to L4 of the first optical element 20 and the second optical element 30, there is no difference in optical coupling efficiency of each of the light beams emitted from the first optical element 20 between the first optical element 20 and the second optical element 30 via the lens elements 41 to 44 of the lens array 40. Moreover, the light beams emitted from the first optical element 20 are received by the second optical element 30 with excellent efficiency.

Here, a comparative example of the optical module according to the first embodiment is described with reference to FIGS. 5 to 7.

In the comparative example, the interference suppression portion 47 is eliminated from the optical module according to the first embodiment.

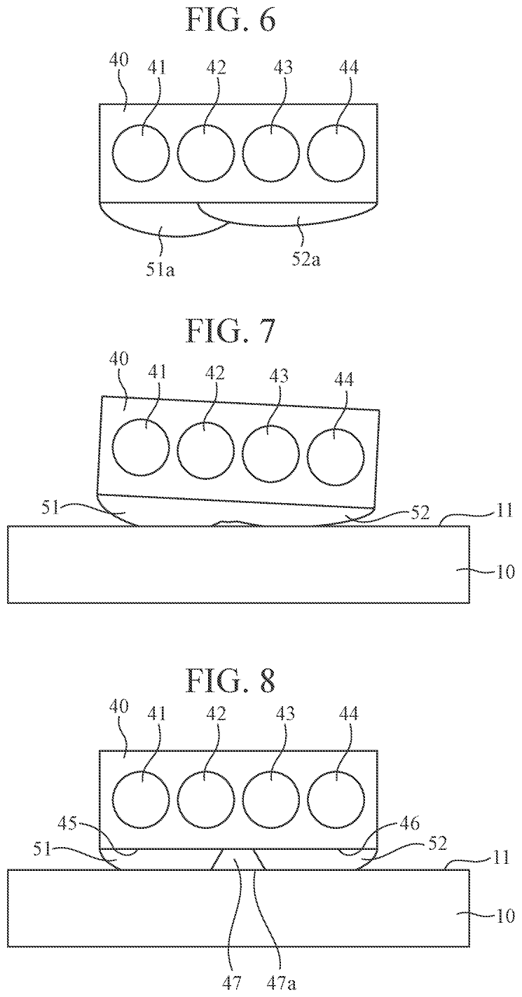

In the comparative example, in a case where the lens array 40 is mounted on the horizontal surface 11 of the base 10 similarly to the optical module according to the first embodiment, first, as illustrated in FIG. 5, the adhesive resin 51a is applied to the first adhesive surface 45 of the lens array 40. Subsequently, as illustrated in FIG. 6, the adhesive resin 52a of the same application amount as the application amount of the adhesive resin 51a is applied to the second adhesive surface 46 of the lens array 40.

The adhesive resin 51a and 52a has viscosity, so that the adhesive resin 52a applied later flows to the adhesive resin 51a. Thus, interference occurs between the adhesive resin 51a and the adhesive resin 52a, and the thickness of the application film of the adhesive resin 52a is thinner than that of the adhesive resin 51a. Thus, there is a difference in thickness of the application film between the adhesive resin 51a and the adhesive resin 52a.

In this state, when the lens array 40 is glued to the horizontal surface 11 of the base 10 by curing the adhesive resin 51a and the adhesive resin 52a as illustrated in FIG. 7, shrinkage depending on the application thickness occurs in each of the adhesive resin 51a and the adhesive resin 52a. The adhesive layer 52 is thinner than the adhesive layer 51. Although the lens array is firmly fixed to the horizontal surface 11 of the base 10 at two points in the lateral direction, the lens array 40 is inclined in the lateral direction with respect to the horizontal surface 11 of the base 10 in such a manner that the adhesive layer 52 side is low.

As a result, there is a difference in optical coupling efficiency of each of the light beams emitted from the first optical element 20 between the first optical element 20 and the second optical element 30 via the lens elements 41 to 44 of the lens array 40.

As described above, in the optical module according to the first embodiment, the lens array 40 includes the plurality of adhesive surfaces 45 and 46, and the interference suppression portion 47 for the adhesive between the adjacent adhesive surfaces 45 and 46. The optical module according to the first embodiment is provided with the plurality of adhesive layers 51 and 52 fixed to the horizontal surface 11 of the base 10 between the plurality of adhesive surfaces 45 and 46 and the horizontal surface 11 of the base 10. Thus, the inclination of the lens array 40 with respect to the horizontal surface 11 of the base 10 is suppressed, and the lens array 40 is firmly fixed to the horizontal surface 11 of the base 10.

As a result, in the optical module according to the first embodiment, there is no difference in optical coupling efficiency of each of the light beams emitted from the first optical element 20 between the first optical element 20 and the second optical element 30 via the lens elements 41 to 44 of the lens array 40. Moreover, the light beams emitted from the first optical element 20 are received by the second optical element 30 with excellent efficiency.

### Second Embodiment

An optical module according to a second embodiment is described with reference to FIG. 8.

In the optical module according to the first embodiment, a cross-sectional surface of the protrusion, which is the interference suppression portion 47, is rectangular. On the other hand, the optical module according to the second embodiment has a trapezoidal cross-sectional surface with a longer lower side. The optical module according to the second embodiment is different from the optical module according to the first embodiment in this point, and is the same in other points.

In FIG. 8, the same reference sign as that in FIGS. 1 to 4 represents the same or corresponding portion.

The optical module according to the second embodiment configured in this manner also has an effect similar to that of the optical module according to the first embodiment. Further, the protrusion, which is an interference suppression portion 47, has the trapezoidal cross-sectional surface with the longer lower side, so that the interference can be further suppressed by surface tension of the adhesive resin 51a and 52a applied to the first adhesive surface 45 and the second adhesive surface 46, respectively.

### Third Embodiment

An optical module according to a third embodiment is described with reference to FIGS. 9 to 11.

In the optical module according to the first embodiment, the first adhesive surface 45 is the bottom surface of the lens array 40 located on one side in the lateral direction and the second adhesive surface 46 is the bottom surface of the lens array 40 located on the other side in the lateral direction. On the other hand, in the optical module according to the third embodiment, a first adhesive surface 45 is a surface which belongs to a protrusion 48 and which faces a horizontal surface 11 of a base 10 and a second adhesive surface 46 is a surface which belongs to a protrusion 49 and which faces the horizontal surface 11 of the base 10. This is the difference. The protrusion 48 protrudes from a bottom surface of a lens array 40 located on one side in the lateral direction toward the horizontal surface 11 of the base 10 with respect to a surface facing the horizontal surface 11 of the base 10. The protrusion 49 protrudes from a bottom surface of the lens array 40 located on the other side in the lateral direction toward the horizontal surface 11 of the base 10 with respect to the surface facing the horizontal surface 11 of the base 10.

An interference suppression portion 47 of the lens array in the optical module according to third embodiment is a space located between the adjacent protrusions 48 and 49.

That is, the optical module according to the third embodiment is different from the optical module according to the first embodiment only in that the protrusions 48 and 49 on which the adhesive surfaces are formed are provided and in the interference suppression portion 47. Other components are the same.

In FIGS. 9 to 11, the same reference sign as that in FIGS. 1 to 4 represents the same or corresponding portion.

In short, the lens array 40 in the optical module according to the third embodiment includes the protrusions 48 and 49 which protrude from the bottom surface facing the horizontal surface 11 of the base 10 and which are located side by side in the lateral direction. The surfaces of the plurality of protrusions 48 and 49 facing the horizontal surface 11 of the base 10 are the adhesive surfaces 45 and 46. The space located between the adjacent protrusions 48 and 49 out of the plurality of protrusions 48 and 49 serves as the interference suppression portion 47 for the adhesive resin applied to the adhesive surfaces 45 and 46.

Each of the protrusions 48 and 49 is a rectangular parallelepiped metal body.

The adhesive surfaces 45 and 46 of the protrusions 48 and 49 have the same area.

The protrusions 48 and 49 formed as separate bodies on the bottom surface of the lens array 40 are illustrated, but may be formed integrally with the bottom surface of the lens array 40. In a case where they are integrally formed, they are simultaneously formed when the lens array 40 is formed.

Although there are two protrusions 48 and 49 including the adhesive surfaces 45 and 46, respectively, in this example, three or more protrusions may be arranged at equal intervals. In this case, the adhesive surfaces of the three or more protrusions have the same area.

In a case where the three or more protrusions are arranged, the interference suppression portion 47 is a space located between the adjacent protrusions.

Adhesive layers 51 and 52 are adhesive layers that glue the plurality of adhesive surfaces 45 and 46 in the protrusions 48 and 49 provided on the lens array 40 to the horizontal surface 11 of the base 10 to fix the lens array 40 to the horizontal surface 11 of the base 10.

In the optical module according to the third embodiment also, similarly to the optical module according to the first embodiment, the lens array 40 is mounted on the horizontal surface 11 of the base 10.

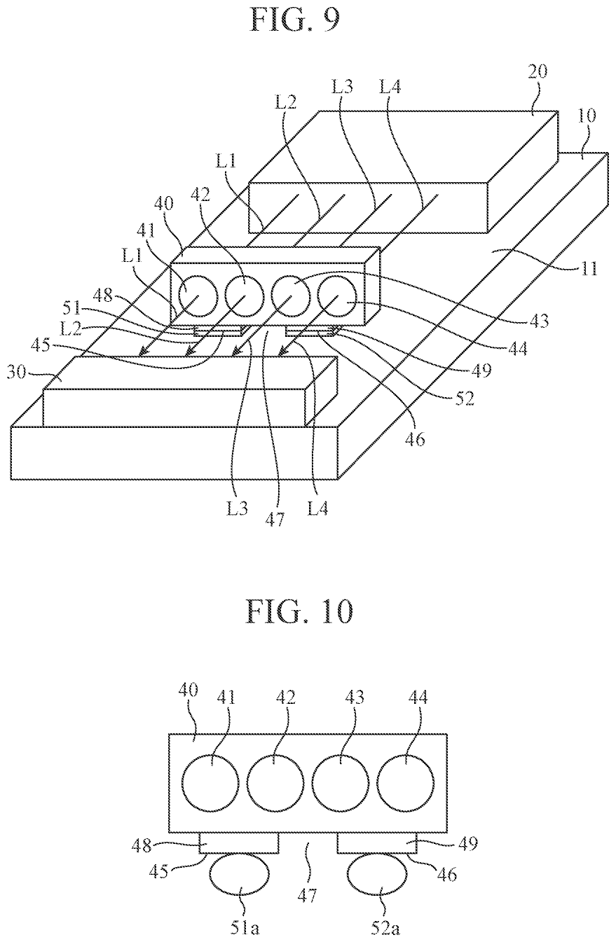

That is, as illustrated in FIG. 10, adhesive resin 51a is applied to the first adhesive surface 45 out of the plurality of adhesive surfaces 45 and 46 in the plurality of protrusions 48 and 49 of the lens array 40, then adhesive resin 52a of the same application amount as that of the adhesive resin 51a is applied to the second adhesive surface 46.

Although the adhesive resin 51a and 52a has viscosity, the interference suppression portion 47 prevents the adhesive resin 52a applied later from flowing to the adhesive resin 51a. Thus, no interference occurs between the adhesive resin 51a and the adhesive resin 52a, and there is no difference in thickness of the application film between the adhesive resin 51a and the adhesive resin 52a. Thus, the application films of the adhesive resin 51a and the adhesive resin 52a have the same thickness.

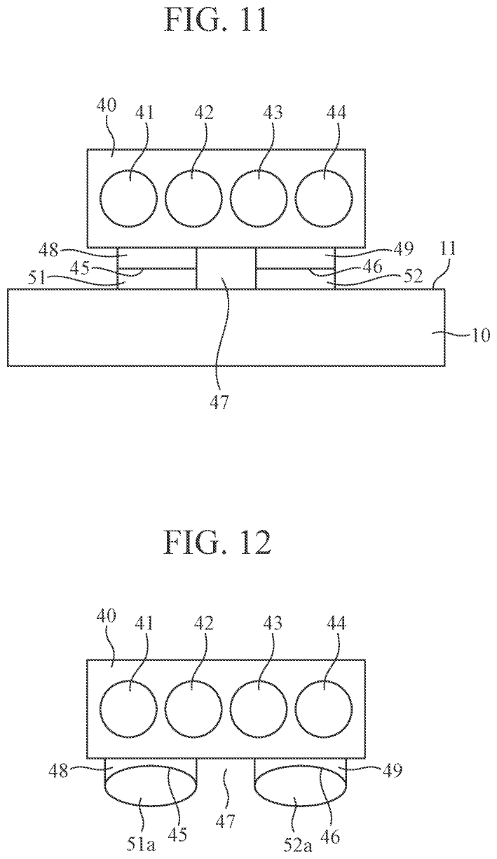

In this state, the adhesive resin 51a and the adhesive resin 52a are cured with the first adhesive surface 45 and the second adhesive surface 46 in the lens array 40 pressed against the horizontal surface 11 of the base 10, as illustrated in FIG. 11. Thereby, the adhesive layers 51 and 52 glue the adhesive surfaces 45 and 46 of the lens array 40 to the horizontal surface 11 of the base 10, respectively, to firmly fix the lens array 40 to the horizontal surface 11 of the base 10 at two points in the lateral direction.

When the adhesive resin 51a and 52a is cured, shrinkage depending on the application thickness occurs in each of the adhesive resin 51a and the adhesive resin 52a. However, since the thickness of the application film of the adhesive resin 51a is the same as that of the adhesive resin 52a, the thicknesses of the adhesive layer 51 and the adhesive layer 52 are also the same.

As a result, the lens array 40 is not inclined in the lateral direction with respect to the horizontal surface 11 of the base 10 even though the lens array 40 is long in the lateral direction. That is, each of the cores (centers) of the plurality of lens elements 41 to 44 of the lens array 40 is located on a plane parallel to the horizontal surface 11 of the base 10, and is located on the corresponding one of the optical axes L1 to L4 of the first optical element 20 and the second optical element 30. Since each of the cores (centers) of the plurality of lens elements 41 to 44 of the lens array 40 is located on the corresponding one of the optical axes L1 to L4 of the first optical element 20 and the second optical element 30, there is no difference in optical coupling efficiency of each of the light beams emitted from the first optical element 20 between the first optical element 20 and the second optical element 30 via the lens elements 41 to 44 of the lens array 40. Moreover, the light beams emitted from the first optical element 20 are received by the second optical element 30 with excellent efficiency.

As described above, in the optical module according to the third embodiment, the lens array 40 includes the plurality of protrusions 48 and 49 protruding from the bottom surface facing the horizontal surface 11 of the base 10 and located side by side in the lateral direction. The surfaces of the plurality of protrusions 48 and 49 facing the horizontal surface 11 of the base 10 are the adhesive surfaces 45 and 46. The space located between the adjacent protrusions 48 and 49 out of the plurality of protrusions 48 and 49 serves as the interference suppression portion 47 for the adhesive resin applied to the adhesive surfaces 45 and 46. Thus, the inclination of the lens array 40 with respect to the horizontal surface 11 of the base 10 is suppressed, and the lens array 40 is firmly fixed to the horizontal surface 11 of the base 10.

As a result, in the optical module according to the third embodiment, there is no difference in optical coupling efficiency of each of the light beams emitted from the first optical element 20 between the first optical element 20 and the second optical element 30 via the lens elements 41 to 44 of the lens array 40. Moreover, the light beams emitted from the first optical element 20 are received by the second optical element 30 with excellent efficiency.

### Fourth Embodiment

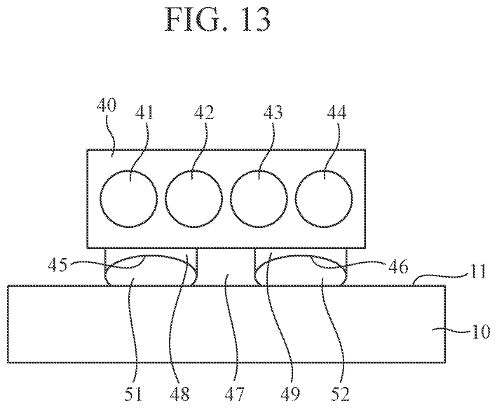

An optical module according to a fourth embodiment is described with reference to FIGS. 12 to 13.

The optical module according to the fourth embodiment is different from the optical module according to the third embodiment in that each of the surfaces of the protrusions 48 and 49 facing the horizontal surface 11 of the base 10 in the optical module according to the third embodiment is made a part of a spherical surface recessed inward, and the part of the spherical surface is made each of adhesive surfaces 45 and 46. They are the same in other points.

In FIGS. 12 and 13, the same reference sign as that in FIGS. 9 to 11 represents the same or corresponding portion.

Note that, although each of the adhesive surfaces 45 and 46 is the part of the spherical surface obtained by recessing inward the surfaces of the protrusions 48 and 49 facing the horizontal surface 11 of the base 10, the adhesive surfaces 45 and 46 are not limited to the spherical surfaces. In short, each of the adhesive surfaces 45 and 46 may be any surface recessed inward.

The optical module according to the fourth embodiment configured in this manner also has an effect similar to that of the optical module according to the third embodiment. In addition, since the first adhesive surface 45 and the second adhesive surface 46 are the surfaces recessed inward of the protrusions 48 and 49, interference can be further suppressed by surface tension of adhesive resin 51a and 52a applied to the first adhesive surface 45 and the second adhesive surface 46.

Note that, in the optical modules according to the first to fourth embodiments, the examples in which the first optical element 20 and the second optical element 30 are directly fixed to the horizontal surface 11 of the base 10 are illustrated, but the first optical element 20 and the second optical element 30 may be each mounted on a submount such as a ceramic substrate, and each of the first optical element 20 and the second optical element 30 may be fixed to the horizontal surface 11 of the base 10 in a state of being mounted on the submount.

In the optical modules according to the first to fourth embodiments, four optical axes are illustrated, but the number thereof is not limited to four, and it is only required that a plurality of optical axes is used.

In the optical modules according to the first to fourth embodiments, the example in which the plurality of optical axes L1 to L4 is located in parallel at regular intervals on the plane parallel to the horizontal surface 11 of the base 10; however, they may be shifted in the height direction, and may be arrayed two-dimensionally, for example, in 2×2, on a vertical surface perpendicular to the horizontal surface 11 of the base 10 and facing the first optical element 20 and the second optical element 30.

In the optical modules according to the first to fourth embodiments, the light is emitted from the first optical element 20 to the second optical element 30 along all the optical axes L1 to L4; however, in a part thereof, the light may be emitted from the second optical element 30 to the first optical element 20 along the optical axes L1 to L4.

In the optical modules according to the first to fourth embodiments, one lens array 40 is disposed between the first optical element 20 and the second optical element 30, but a plurality of lens arrays 40 may be arranged in parallel between the first optical element 20 and the second optical element 30. At that time, all the plurality of lens arrays 40 is fixed to the base 10 as described with the optical modules according to the first to fourth embodiments.

In the optical modules according to the first to fourth embodiments, the example in which the base 10 is made horizontal is described; however, the base 10 may be made vertical, and the first optical element 20, the second optical element 30, and the lens array 40 may be arranged on a vertical flat surface, which is a flat surface, or the base 10 may be made oblique, and they may be arranged on an inclined flat surface, which is a flat surface.

Note that, the embodiments may be freely combined, any component of each embodiment may be modified, or any component may be omitted in each embodiment.

### INDUSTRIAL APPLICABILITY

The optical module according to the present disclosure is suitable for an optical module which is used in the field of optical communication devices and which is provided with a lens array including a plurality of lens elements arranged in parallel.

### REFERENCE SIGNS LIST

10: base, 11: horizontal surface, 20: first optical element, 30: second optical element, 40: lens array, 41 to 44: lens element, 45, 46: adhesive surface, 47: interference suppression portion, 48, 49: protrusion, 51: first adhesive layer, 52: second adhesive layer

1. An optical module comprising:
a base including a flat surface;
a semiconductor light emitter and a semiconductor light receiver arranged in such a manner as to face each other on the flat surface of the base, the semiconductor light emitter and the semiconductor light receiver each including a plurality of parallel optical axes, the semiconductor light emitter being to emit light to the plurality of optical axes, the semiconductor light receiver being to receive the light emitted from the semiconductor light emitter to the plurality of optical axes; and
a lens array disposed on the flat surface of the base between the semiconductor light emitter and the semiconductor light receiver, the lens array including a plurality of lens elements arranged in parallel, the plurality of lens elements corresponding to the respective plurality of optical axes of each of the semiconductor light emitter and the semiconductor light receiver, the plurality of lens elements optically coupling the semiconductor light emitter to the semiconductor light receiver,
wherein
the lens array includes, on a surface which belongs to the lens array and which faces the flat surface of the base, a plurality of adhesive surfaces located side by side in a direction in which the plurality of lens elements is arranged in parallel, and includes an interference suppression portion for an adhesive between adjacent adhesive surfaces among the plurality of adhesive surfaces, and
a plurality of adhesive layers is provided which glues the respective plurality of adhesive surfaces of the lens array to the flat surface of the base and thereby fixes the lens array to the flat surface of the base.

2. The optical module according to claim 1, wherein the plurality of optical axes of each of the semiconductor light emitter and the semiconductor light receiver is located on a plane parallel to the flat surface of the base.

3. The optical module according to claim 1, wherein the interference suppression portion of the lens array is a protrusion protruded toward the flat surface of the base with respect to the plurality of adhesive surfaces.

4. The optical module according to claim 3, wherein the protrusion includes a joining flat surface in contact with the flat surface of the base.

5. The optical module according to claim 1, wherein
each of the adhesive surfaces of the lens array is a corresponding one of surfaces which belong to respective protrusions and which face the flat surface of the base, the protrusions being protruded toward the flat surface of the base with respect to the surface which belongs to the lens array and which faces the flat surface of the base, and
the interference suppression portion of the lens array is a space located between adjacent two of the protrusions.

6. The optical module according to claim 5, wherein each of the surfaces which belong to the respective protrusions and which face the flat surface of the base is a surface recessed inward.
